(19) United States
(12) Patent Application Publication
(10) Pub. No.: US 2010/0172383 A1
(43) Pub. Date: Jul. 8, 2010

(54) Multivariable control system with state feedback

(75) Inventors: Armando Montalvo, Woodland Hills, CA (US); Albert Garden, Woodland Hills, CA (US)

Correspondence Address: FULWIDER PATTON LLP, HOWARD HUGHES CENTER, 6060 CENTER DRIVE, TENTH FLOOR, LOS ANGELES, CA, 90045, US

(73) Assignee: SABEUS, INC., Calabasas, CA (US)

(21) Appl. No.: 11/816,330

(22) PCT Filed: Mar. 9, 2006
(86) PCT No.: PCT/US06/08746

§ 371 Date: Feb. 17, 2009

Related U.S. Application Data
(60) Provisional application No. 60/660,429, filed on Mar. 9, 2005.

(51) Int. Cl. H01S 3/10; H01S 5/06

(52) U.S. Cl. 372/38.01; 372/43.01

(57) ABSTRACT

A system and method for controlling the output of a semiconductor laser is presented. The system and method includes using non-linear equations to calculate a state space model of the laser around an operating point. Adaptive algorithms are calculated and control signals determined using a controller to determine appropriate control laws and cost functions, which are then optimized and used to feed back a control signal to the semiconductor laser to improve the performance and stabilize the output of the laser.

### CROSS-REFERENCES TO RELATED APPLICATIONS

This application claims the benefit of priority to U.S. Provisional Application No. 60/660,429, filed Mar. 9, 2005, the subject matter of which is being incorporated herein in its entirety.

### BACKGROUND OF THE INVENTION

1. Field of the Invention

This invention relates generally to wavelength control systems for light sources, and more particularly, to wavelength control systems that use conventional semiconductor light sources.

2. Background

Semiconductor based lasers are relatively inexpensive wavelength sources that are used today for many applications. As a wavelength source, semiconductor lasers are can be imperfect, suffering from substantial amounts of frequency jitter (long and short term), phase jitter, and phase noise variance. Moreover, such lasers typically have a small signal with large intensity variations, large line widths and the like. These imperfections impose limitations on the number of applications to which these lasers can be applied. For example, highly stable and accurate lasers are required in fiber sensing applications where highly stable and low noise light sources are needed to perform high precision interferometric measurements. Other (non-semiconductor) laser sources can be used for these applications; however, these laser sources are expensive and not practicable as field deployable units.

What has been needed, and heretofore unavailable, is a relatively inexpensive, easy to manufacture and align, semiconductor laser having reduced amounts of frequency jitter, phase jitter and phase noise variance. Such a laser would also have improved signal to phase noise ratio, lowered relative intensity noise and smaller line widths to provide a stable and accurate wavelength source. The present invention fulfils these and other needs.

### SUMMARY OF THE INVENTION

The present invention solves the above problems and, through the use of multivariable optimal feedback control techniques, an improved performance of an ordinary semiconductor wavelength source results so than an inexpensive, robust, highly stable and low noise wavelength source results that can be used for many applications, including, but not limited to, interferometric measurements of fiber sensor applications, such as, for example, seismic exploration, structural health, and the like. Additionally, with the present invention, the inherent long and short term frequency jitter, inherent line width and the overall low frequency phase noise of the laser are reduced by multiple factors, which all contribute to the lowest noise obtained for a semiconductor laser.

In another aspect, the present invention comprises a wavelength source control system, comprising an optical control feedback element; a wavelength source element coupled to the optical control feedback element; wherein the optical control feedback element is adapted to: sample a wavelength source element output; determine an error signal based on the sampled wavelength source element output; and transmit a set of control signals comprising a current control signal and temperature control signal to the wavelength source element wherein the set of control signals are based on the error signal and a frequency of the output, a temperature of the wavelength source element and an output power of the wavelength source element. In an alternative aspect, the optical control feedback element comprises an optical source reference, an analog feedback and a digital control element adapted to generate the current control signal and temperature control signal. In yet another alternative aspect, the wavelength source element comprises a laser, laser driver and temperature control element.

In still another aspect, the present invention includes a wavelength source control method, comprising: sampling a wavelength source element output; determining an error signal based on the sampled wavelength source element output; and transmitting a set of control signals comprising a current control signal and temperature control signal wherein the set of control signals are based on the error signal and a frequency of a wavelength source element, a temperature of the wavelength source element and an output power of the wavelength source element.

In a still further aspect, the invention includes a method for controlling the wavelength output of a laser, comprising: sampling an output of a laser; determining a control law related to at least one selected parameter that is an input of the laser; applying the control law to the output of the laser; and operating the laser in accordance with the control law. In an alternative aspect, determining the control law includes determining a cost function related to the output of the laser.

In still another aspect, the invention further comprises optimizing the cost function to obtain a desired operational condition of the laser. In yet another aspect, sampling the output of the laser includes sampling an intensity parameter and a temperature parameter. In a still further aspect, the control law is applied to alter the intensity of the laser, and in an alternative aspect, the control law is applied to alter the temperature of an active region of the laser.

In a further aspect, determining a control law includes comparing the output of the laser to a response of an optical cavity. In still another aspect, determining a control law includes determining an error signal.

Another aspect of the invention includes determining an error signal including smoothing the error signal to remove background noise from the signal, and in yet another aspect, the invention includes determining a control law in a manner that includes non-linear minimization and parameter estimation and determining a space state model of the laser.

Instill another aspect, sampling the output of the laser includes splitting the output of the laser using a beam splitter into a first beam and a second beam, splitting the second beam into a third beam and a fourth beam using a polarizing beam splitter, communicating the third beam to an optical cavity, sampling an output of the optical cavity, communicating the sampled output of the optical cavity to a first photodector, communicating the fourth beam to a second photodetector, determining an error signal from an output from the first photodetector and the second photodetector. In yet another aspect, the laser is a semiconductor laser.

Other features and advantages of the invention will become apparent from the following detailed description, taken in conjunction with the accompanying drawings, which illustrate, by way of example, the features of the invention.

### BRIEF DESCRIPTION OF THE DRAWINGS

FIG. 1 is block diagram illustrating showing processing steps and information flow through one embodiment of the present invention;

FIG. 2 is a block diagram illustrating details of one implementation of hardware and software capable of carrying out the processes of the embodiment of FIG. 1;

FIG. 3 is a graphical representation normalized light/time an normalized carrier/time as a function of time/photon lifetime;

FIG. 4 is a graphical representation showing the relationship of laser power and laser output frequency as a function of bias current and junction temperature;

FIG. 5 is a graphical representation showing the laser frequency and output power change as a function of bias current and junction temperature;

FIG. 6 is a block diagram showing additional details of the system of FIG. 2;

FIG. 7A is a graphical representation showing Fineness of the cavity as function of reflectivity;

FIG. 7B is a graphical representation showing fineness of the cavity as function of reflectivity similar to the graph of FIG. 7A except graphed using a logarithmic scale;

FIG. 8A is a graphical representation of cavity reflectance frequency as a function of frequency;

FIG. 8B is a graphical representation of cavity frequency response as a function of frequency;

FIG. 9 is a block diagram illustrating details of a loop filter and control law in accordance with principles of the present invention;

FIG. 10A is a block diagram illustrating a portion of one embodiment of an adaptive algorithm used to improve the performance of the semiconductor laser;

FIG. 10B is a block diagram illustrating a portion of one embodiment of an adaptive algorithm used to improve the performance of the semiconductor laser;

FIG. 10C is a block diagram illustrating a portion of one embodiment of an adaptive algorithm used to improve the performance of the semiconductor laser;

FIG. 10D is a block diagram illustrating a portion of one embodiment of an adaptive algorithm used to improve the performance of the semiconductor laser;

FIG. 10E is a block diagram illustrating a portion of one embodiment of an adaptive algorithm used to improve the performance of the semiconductor laser;

FIG. 11 is a graphical representation of intensity errors as a function of time;

FIG. 12A is a graphical representation of intensity values as a function of time;

FIG. 12B is a graphical representation of intensity ration as a function of time;

FIG. 12C is a graphical representation of intensity ratio as a function of time;

FIG. 13A is a graphical representation of laser delta phase per loop as a function of time;

FIG. 13B is a graphical representation of laser output frequency as a function of time;

FIG. 14 is a block diagram illustrating another embodiment of the system of the present invention;

FIG. 15 is a graphical representation of laser response as a function of frequency showing the improvement in laser performance for a laser controlled in accordance with the principles of the present invention compared to a DFB laser without control and a fiber laser.

### DETAILED DESCRIPTION OF THE PREFERRED EMBODIMENTS

Referring to the drawings, in which like elements of the several views are similarly numbered, there are shown exemplary embodiments of a system and method configured as a source of light having a highly controlled wavelength and intensity that may be used in a variety of fiber sensor applications. As will be discussed in more detail below, light sources, particularly those using relatively low cost semiconductor lasers, may be provided having greatly improved control of the emitted light source, providing, for example, much lower frequency jitter, better signal to noise ratios and improved low frequency phase noise, for example. The present invention uses adaptive control algorithms to control several performance variables in a semiconductor laser such as, for example, line width, phase, noise, short and long term frequency stability, light intensity noise and the like.

As those skilled in the art understand, a semiconductor laser can be described by a pair of nonlinear-differential equations which relate to photon and electron density within an active region of the semiconductor laser. In order for lasing to occur, carriers need to jump state. The term “jumping state” relates to photons—which condition should be maintained every time electrons give energy to a particular photon in a sustained manner.

When a proper electromagnetic bias field and temperature is supplied to the active region in a semiconductor laser, the electron-holes carriers are exited to jump state and generate photons in a sustained manner which creates a lasing condition within the active region of the semiconductor laser. However, once the lasing condition is sustained, the performance of the semiconductor laser is very poor. Semiconductor lasers typically have intensity loss in the frequency domain, and exhibit very high phase noise, very broad line width and very broad frequency jitter and intensity noise which are a function of current and temperature bias fluctuations as well as spontaneous recombination of electron hole pairs in the active region of the laser.

The inventors of the present invention have determined that when the temperature and current input state variables of the laser and lasing condition are varied, as defined in the above-mentioned non-linear and coupled differential equations, in order to optimize and minimize the random effect of recombination electron whole pairs in the active region of the laser, the laser performance is improved with respect to frequency stability, phase noise, power stability, line width and the like. The present invention, in general terms, uses adaptive control and estimation techniques to address the characteristics that govern the combinational effects within the laser.

The system and method of the present invention controls the performance of the laser by sensing the performance of the laser and compares the performance of the laser to a reference optical cavity that is tuned so that the performance of the cavity is well known, understood and controlled using estimation and adaptive control techniques to develop a control signal that modifies the performance of the laser. Once the laser is behaving substantially equal to the behavior of the reference optical cavity, that level of behavior becomes the laser's operating point. This operating point is used as a point of perturbation in order to simplify the highly coupled nonlinear differential equations into a set of linear differential equations that describe the behavior of the semiconductor laser around the operation point.

The performance of the semiconductor laser around this operating point is accordingly represented as governed by a set of linear state space differential equations whose space state variables describe and measure the performance of the electron-hole pair densities inside the active region of the laser and thus governs the performance of the semiconductor laser. Since all performance properties of the semiconductor laser can be described as functions of these state variables, an optimization cost function can be derived that compares the performance properties of the laser with those of a desired optimal laser.

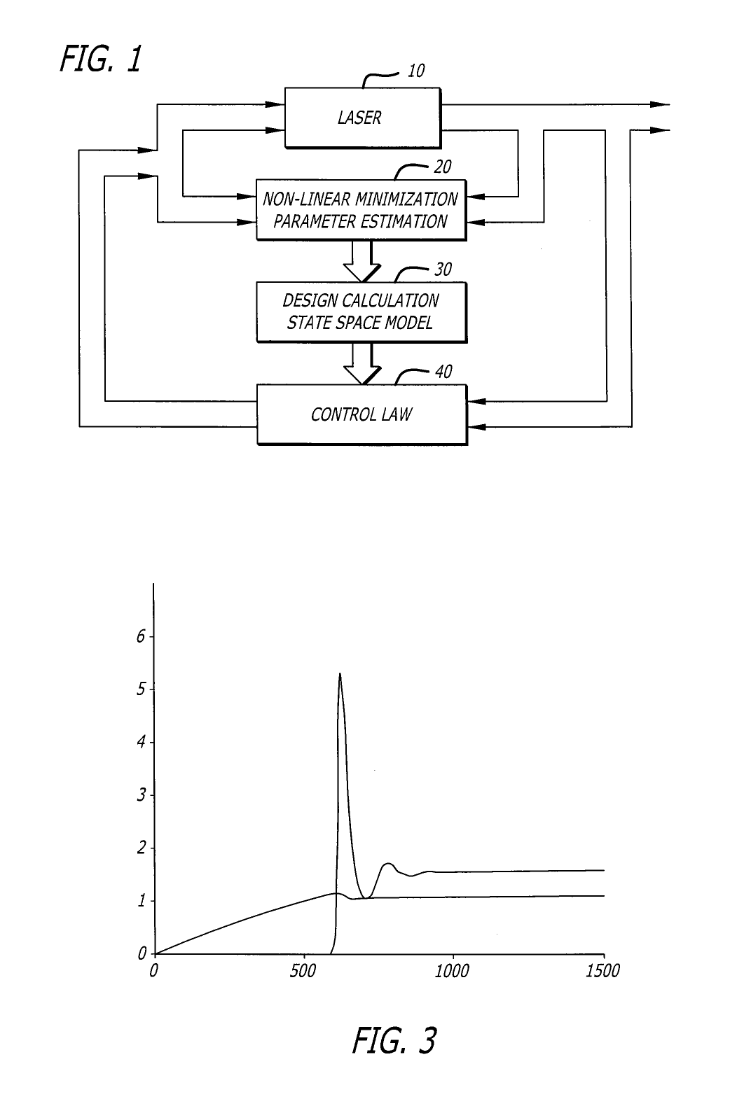

Perturbation adaptive control techniques are also used in order to find the optimum control laws that minimize the cost function that heightens the particular performance of the laser, such as, for example, to improve frequency stability, reduce phase noise and phase jitter, decrease of line width, and the like. As can be seen in FIG. 1, once the operating point is achieved and the laser operating characteristics are close to the operating characteristics of the reference cavity, optimum control theory using one or more cost functions, along with the simplified test space variable model to rely on optimal control law, is used to feedback perturbations in temperature and current around the operating point of the laser in order to correctively drive the semiconductor laser.

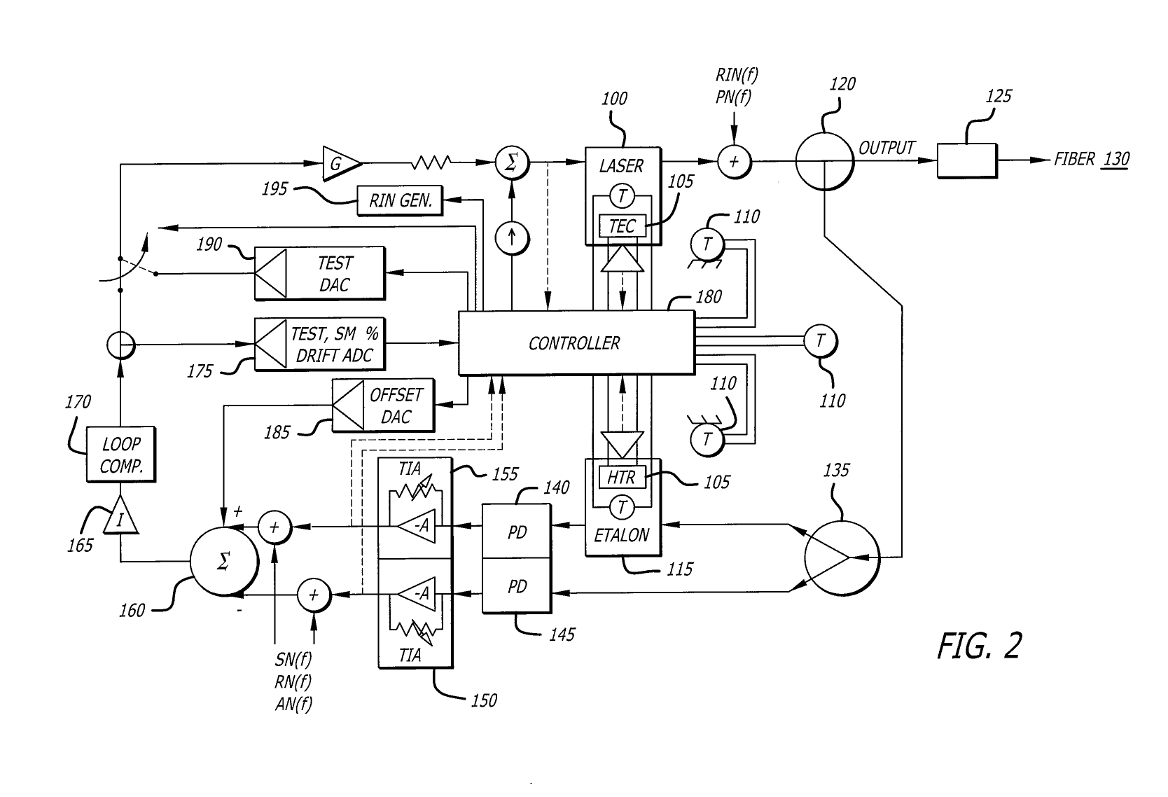

One embodiment of a system block diagram capable of carrying out the principles of the present invention is illustrated in FIG. 2. In this embodiment, a laser die chip 100 such as, for example, an EFB65073831 sold by NEC is used as a light source. Additionally, the system includes several types of thermo-electric coolers 105, such as, for example, an SPS374-301 sold by BCN, together with one or more thermocouples 110. The thermo-electric coolers 105 and thermocouples 110 are used as temperature feedback elements to control the operating temperature of the semiconductor laser 100 and a reference cavity 115, such as an Etalon.

The light beam output from the laser 100 is passed through a beam splitter 120. The beam splitter is preferably a 10/90 or 5/95, such as a PBS-1550-10-020-5 sold by BS. By 5/95, it is meant that the beam splitter 120 directs 95 percent of the laser energy into a collimator 125 that directs the output beam into a fiber 130. The remaining 5 percent is directed to a second beam splitter 135, such as a PBS-1550-50/50, which polarizes the beam and passes the a portion of the light to the upper reference optical cavity 115 and then to a photodetector 140.

The optical cavity 115 behaves as an aliased high “Q” bandpass resonator circuit whose resonation frequencies are controlled by the optical separation of the mirrors inside the optical cavity, that is, the free spectral range of the cavity and the “Q” is controlled by the fineness of the optical cavity. In the present invention illustrated in FIG. 2, a particular wavelength reacts to the optical cavity 115. If the laser wavelength is not close to the frequency of the cavity, the cavity response will be zero (or close to zero). When the laser wavelength is close to the frequency of the cavity, however, the response of the cavity is at its peak (ideally, close to one).

In such case, the optical response and laser output wavelength difference signal indicates how far away the laser wavelength is from the tuned wavelength of the optical cavity. This signal is used as an error signal in the control so that when a change in the current and/or temperature of the laser and/or cavity occur, each can be tuned. As shown in FIG. 2, when the output of the laser 100 is split by beam splitter 120, 5 percent of the optical field of the light beam is diverted to the second polarizing beam splitter 135 that further divides (in substantially equal power) the 5 percent optical field into a photodetector 145 and into optical cavity 115 whose output intensity is monitored by photodetector 140. It will be understood by those skilled in the art that the outputs of photodetectors 140, 145 are proportional to the intensity of the output of the laser 100 and of the response of the optical cavity 115.

Transimpedance amplifiers (TIA)155, such as MAX 3271 sold by Maxum, are used to convert micro-currents at the output of the photodetectors into milli-currents given enough amplification and impedance matching such that the resulting signal can be manipulated by electrical signal processing techniques).

The error signal derived from the outputs of photodetectors 140, 145 is further processed by an error feedback loop filter. One of the purposes of the feedback loop filter is to measure and classify error into its high and low frequency elements. After decomposing the error signal, the resulting error components are sampled by a set of analog to digital converters where the sampled data is then passed through a controller 180. The controller 180 is basically a die of a digital signal processor chip, such as a DSP56F803 sold by Motorola, that is used, by executing a series of software steps, which may either be embedded or impressed upon the controller using techniques well known to those in the art, to find the operating point of the laser, and to perform the essential algorithms or steps required to simplify and find the state space approximation of the semiconductor laser, generate the outputs of the control law required to optimize the variations in temperature and current and set the operating point of the semiconductor laser.

Once the laser and cavity frequency have converged, the controller performs various programming routines using a state space variable approximation for the behavior of the active region in the laser to estimate the performance of the laser in order to control the optimal input temperature and electrical current in order to make the laser behave according to the desired laser performance that minimizes the cost function chosen. The output of the feedback loop is sampled and the data is passed to the controller (which executes the algorithm, i.e., steps) where it is used as input to control the system.

Since the controller does not process analog signals, any external signals need to be converted to digital before entering the controller. Likewise, when a signal comes from the controller, it is in digital form. If an analog signal is needed, the output of the controller needs to be converted to analog.

RIN Generator 195 is a polynomial noise generator that is used as a white noise generator to process the optical signal to smooth out any noise and/or burst errors that still remain in the optical signal. Thermal couples 110 are used to measure the temperature of the laser, cavity and outside package ambient temperature so that if the ambient temperature increases, some compensation can be applied to the laser and/or cavity by changing the DSP control algorithms. As a result of the system and method of the present invention, the frequency of the light output by laser 100 is stabilized since the calculations used to control the feedback system are controlled by the operating characteristics of the optical resonator cavity 115.

There are several advantages of executing the programming steps within a controller. For example, the system performance (overall noise floor) is not controlled by the performance of a differential phase error function that uses jitter on a skewed slope to generate a phase error signal to drive a simple analog control loop, similar to those found in a typical phased locked loop. Since the present invention works directly with frequency and phase error, such limiting differential phase error functions are not used. Moreover, the system is capable of providing inherent compensation for the aging of the electronic components in the creation of the error and controller signals. This compensation is obtained by the differential nature of the mechanism for creating these signals and how they are treated in the optimization algorithms. Additionally, the system and method provide a resonant peak control minima. This occurs because the reference optical cavity 115 only reacts to a unique frequency within its free spectral range and, as a consequence, there is no problem with having a cost function with multiple minimum points within the free spectral range of the reference, that is, multiple means and optimization points that would otherwise converge to false lock conditions are avoided. Since both current and temperature are simultaneously used as controls, better performance, and thus control of combination effects in the active region of the semiconductor laser are observed.

The following equations are examples of nonlinear differential equations describing the performance and the behavior of a typical semiconductor laser with respect to frequency. Those skilled in the art will recognize that other sets of equations directed to other characteristics of the laser, such as RN, wavelength or the like can be used, and are intended to be included in the present invention. These nonlinear differential equations are coupled and describe the entire electron and hole density of the laser and the recombination effects in the active region of the laser as well as the effects of temperature variation and how that governs the generated power and frequency of the laser, among other parameters.

These equations are solved in order to develop the control law that is applied to the inputs and outputs of the laser to control the output performance of the laser:

$$\frac{d N ( t )}{d t} = {η}_{i} \frac{I ( t )}{e V} - {R}_{r} ( N ) - {V}_{g} \tilde{g} ( N ) {N}_{p}$$

$$\frac{d {N}_{P} ( t )}{d t} = Γ {V}_{g} {\tilde{g}}^{( N )} {N}_{P} - \frac{{N}_{P}}{{τ}_{P}} + \frac{Γ {V}_{g} g ( {N}_{sp} )}{{V}_{P}}$$

$${R}_{r} ( N ) = [ AN + {BN}^{2} + {CN}^{3} ] = \frac{N}{{τ}_{N}}$$

$$N = {N}_{Co} {e}^{\frac{T ( t ) {E}_{g}}{{T}_{0} {E}_{v}}}$$

$$λ ( t ) = {λ}_{0} + Δ λ ( t )$$

$$Δ λ ( t ) = \frac{α}{2 {N}_{P 0}} * \frac{d ( {N}_{P} ( t ) - {N}_{P 0} )}{d t}$$

$$P ( t ) = {η}_{0} [ h λ \frac{{V}_{P}}{{τ}_{P}} ] {N}_{P} ( t )$$

where:

N(t)=electron density

Nₚ(t)—photon density

N₀=carrier (electron) density required for transparency

V=Volume of active layer

Rᵣ(N)=polynomial approximation of rate of recombination of carriers in the active region of the laser which includes simulation of defect assisted recombination, surface recombination and Auger recombination effects.

V_{g}=volume of the gain region

\ddot{g}(N)=carrier loss density due to photon generated by stimulated emissions

N_{P0}=photon density at threshold

Γ=optical confinement factor

Nₛₚ=photon production rate due to spontaneous emissions

N_{C0}=electron carrier density at the operating point

τ_{P}=average photon life-time in the active region

V_{P}=effective gain region volume

A=Polynomial constant

B=polynomial constant

C=polynomial constant

τ_{N}=average life-time of electron in the active region

λ₀=wavelength at operating point 0

λ(t)=wavelength

E_{g}=Bond energy gap

E_{V}=1.24 ev constant

T(t)=temperature as function of time

T₀=Temperature at operating point 0

ηᵢ=photon electron efficiency

I(t)=bias current

In the exemplary embodiment presented herein, the differential equations can be solved and the steady state solutions resulting from that solution are used to obtain a frequency at which the wavelength of the photons will sustain a lasing condition and the power at which the semiconductor laser will output.

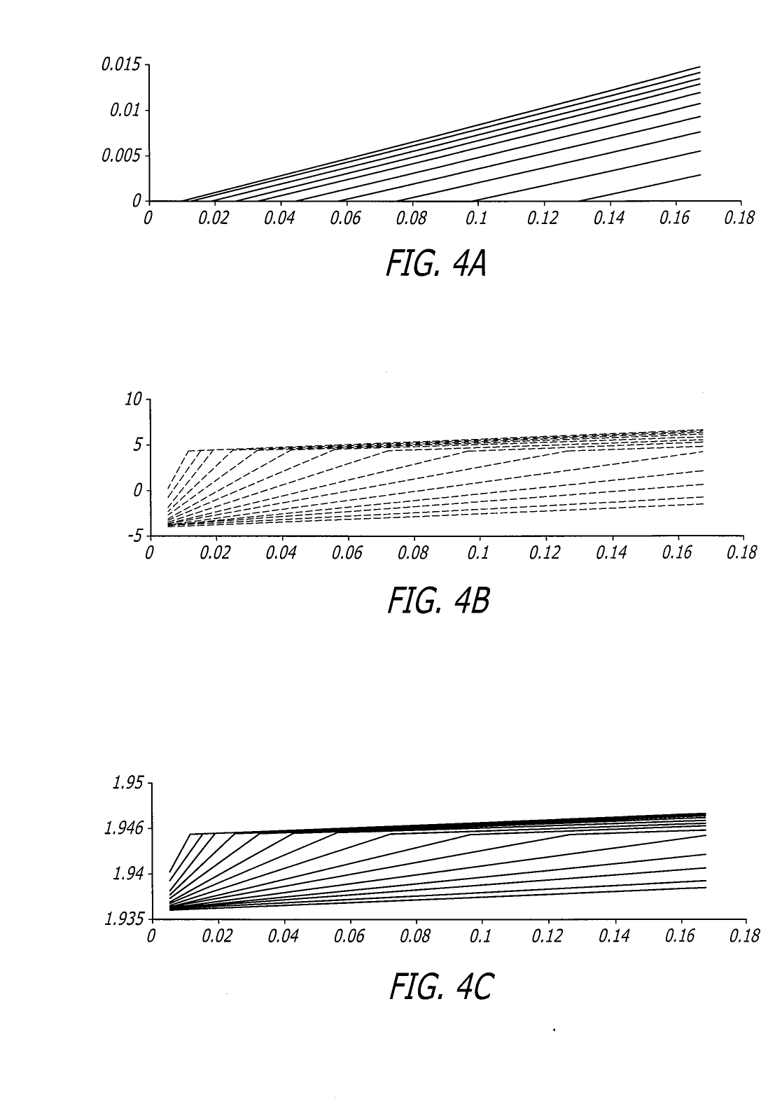

FIG. 3 provides a graphical illustration showing how the output optical power for a typical semiconductor laser varies as a function of a bias current applied to the laser. It can be seen from this graph that where while the bias current falls below a threshold value, no optical power is generated by the laser because a sustained photon generation condition is not yet occurring within the active region of the laser. When the bias current exceeds the threshold value, photons are generated in a sustained manner within the active region of the laser so that an optical power is generated at the laser output. The amount of power and lasing depends on the temperature and bias current at the laser junction, which is illustrated in the graphs of FIGS. 4A, 4B and 4C.

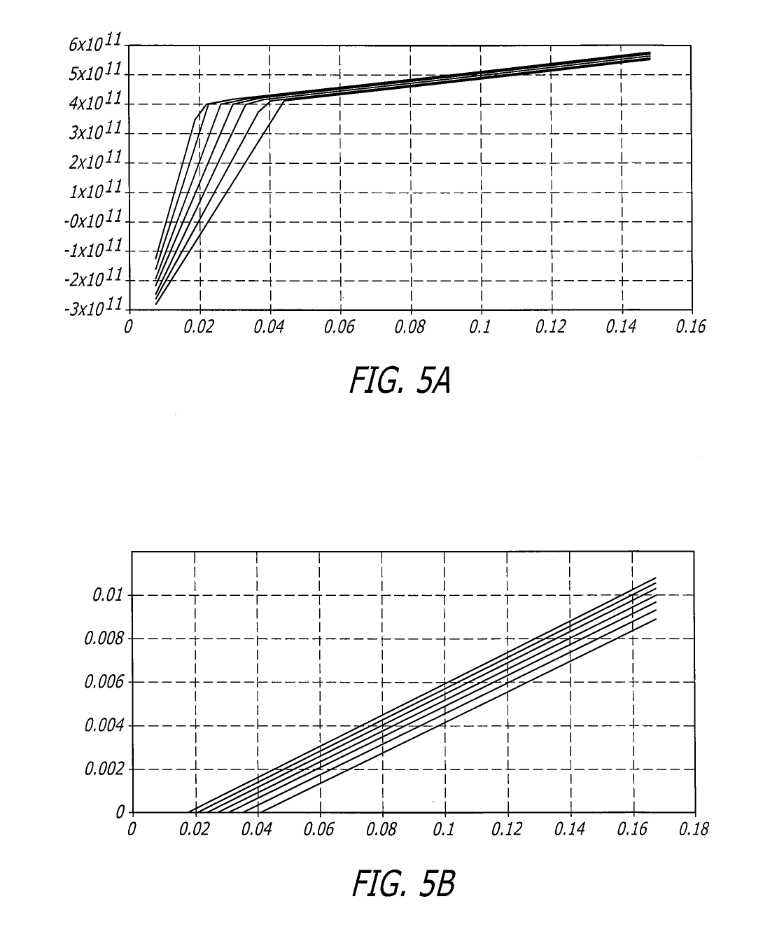

FIGS. 5A and 5B illustrate the partial derivatives of the bias current with respect to temperature which show how the threshold current is changing with respect to temperature in order to maintain constant power output from the laser.

FIGS. 5A and 5B are used to obtain representative values of the partial derivatives of the bias current with respect to temperature and the partial derivatives of power with respect to temperature. This data is used by the system and method of the present invention to guide the algorithms used by the controller to find the optimal operation point solution for the operation of the laser.

As stated previously, the system and method of the present invention utilizes adaptive and estimation algorithms to find the operating point of the semiconductor laser. Once the operating point of the laser is found, the optimization point of the laser can be determined. In other words, the system may vary the current and temperature of the laser to find the optimization point of the laser. This determination is accomplished by assuming that the laser is operating around an operation point (I₀, N₀, N_{P0}, P₀, T₀) and solving the following equations:

I(t)=I₀+Δi(t)=I₀Real{i(ω)e^{jωt}}∥i(ω)∥<<I₀

P(t)=P₀+ΔP(t)=P₀+Real{P(ω)e^{jωt}}

N(t)=N₀+ΔN(t)=N₀+Real{N(ω)e^{jωt}}

Nₚ(t)=N_{P0}+ΔNₚ(t)=Nₚ₀+Real{Nₚ(ω)e^{jωt}}

T(t)=T₀+ΔT(t)=T₀+Real{T(ω)e^{jωt}}

The solid space model is given by:

$$Δ X ( t ) = [ \begin{matrix}Δ N ( t ) \\ Δ {N}_{P} ( t )\end{matrix} ]$$

$${Δ}^{′} X ( t ) = A Δ X ( t ) + B [ \begin{matrix}Δ i ( t ) \\ Δ T ( t )\end{matrix} ]$$

$$Y ( t ) = C Δ X ( t ) + D [ \begin{matrix}Δ i ( t ) \\ Δ T ) t )\end{matrix} ]$$

$$where \text{:}$$

$$A = [ \begin{matrix}\frac{- 1}{{τ}_{r}} - \frac{1}{{τ}_{st}} & \frac{- 1}{Γ {τ}_{p}} \\ \frac{Γ}{τ} & 0\end{matrix} ]$$

$$B = [ \frac{{η}_{i}}{{ev}_{0 }} ]$$

$$C = [ \begin{matrix}0 & \frac{h Ω {v}_{p}}{{τ}_{p}} \\ 0 & \frac{α d}{2 {N}_{P 0}}\end{matrix} ]$$

$$D = 0$$

As illustrated by the above equations, the current and temperature is determined so that the power, electron density, and photon density inside the active region of the laser can be controlled. Consequently, the non-linear differential equations (which are highly coupled) can be substituted by a simpler set of linear differential equations, as illustrated above, where a vector differential equation dX/dt=AX+BU, Y=CX+DU is used to describe the behavior of the laser around an operating point (T₀, I₀, N₀, Np₀, F₀, P₀). Note, for example, the matrix A elements are controlled by (1) recombination time, (2) average lifetime of the electrons inside the effective active region of the semiconductor laser, (3) average effective active region of the laser, (4) average recombination time of the electron hole pairs and (5) stroke time. Gamma (Γ) is the confining factor marking the effective active region of the semiconductor laser and B is the input vector. The first element in B is an efficiency factor (with the efficiency of the photon detector converting photons into electrons) and EV is electron volts (a constant). Vector C is a two by two matrix which is defined by h and omega (Ω), where h is Plank's constant and omega is the frequency of the laser (electrical frequency, Vp is the effective volume, Tau (τ) is a photon recombination time, d is displacement of the active region, and Np₀ is the electron hole steady state solution at the operating point, and α is a proportionality constant that reflects the refractive index oscillation in the active region.

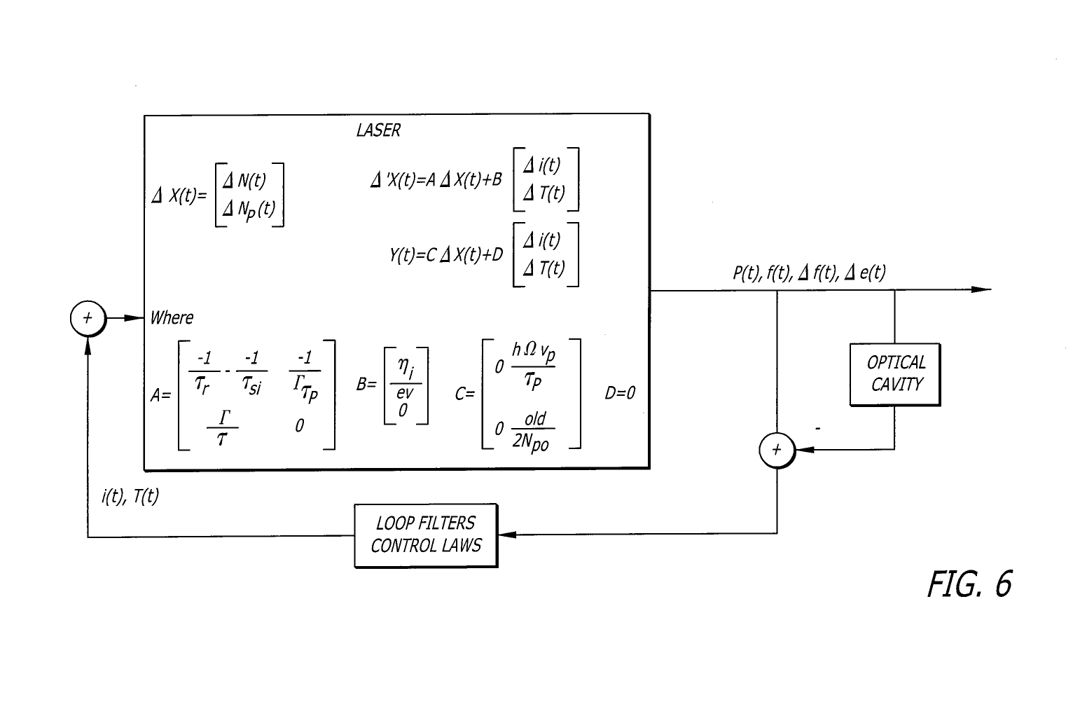

Once the above vector equations have been solved, one embodiment of the invention can be described as a system that can be represented by the model as described in FIG. 6. In this figure, the laser is described by the state space model, where the laser output is compared to the optical cavity response. The error signal is generated and is input to the error conditional filter (the error feedback loop filter) and is then passed in digital form to the controller so that the optimum current and temperature for the laser are generated by the programming of the controller algorithms.

The optical cavity within the laser has a transfer function which describes the optical cavity values and relationships within the laser using the following equations:

$$Fineness = {F}_{R} = \frac{π \sqrt{R}}{1 - R}$$

$${T}_{Etalon} = 1 + \frac{1}{1 + \frac{4 R}{1 - {R}^{2 }} {sin}^{2} ( \frac{π f}{FSR} )}$$

$${\vert \frac{d {T}_{Etalon} ( f )}{d f} \vert}_{T = \frac{T ma x - T m i n}{2}} = \frac{2 π}{FSR} * \frac{2 R ( 1 + {R}^{2} )}{{( 1 + R )}^{2} ( 1 - {R}^{2} )}$$

$${FWHM}_{Etalon} \approx FSR \frac{1 - R}{π \sqrt{R}} \approx Circuit - Locking - Range$$

As is apparent, this function is controlled by several parameters: fineness of the optical cavity, the effective separation of the mirrors or the effective size of the optical cavity (which controls the optical cavity free spectral range, FSR), and the full width half maximum (FWHM) of the cavity response, which can be used in conjunction with the cavity FSR as a measurement of the locking range for this type of control system.

For the purposes of the present invention, an optical cavity is generally defined by two mirrors, an optical ring or some other way of creating an optical cavity. As is well known in the art, such optical cavities sometimes have flatness issues. Typically, two mirrors of the optical cavity are separated by distance d, which serves as the optical cavity. A ring cavity may also used, but microphonic effects may arise. Other types of cavities may also be used but may also be susceptible to microphonic effects. The preferred cavity, as seen here, allows for pressurization and tuning, as is described more fully in PCT. application Ser. No. ______, entitled “A Novel Method to Affix an Optical Element”, which incorporated in its entirety herein, and filed Feb. 24, 2005, without microphonic effects.

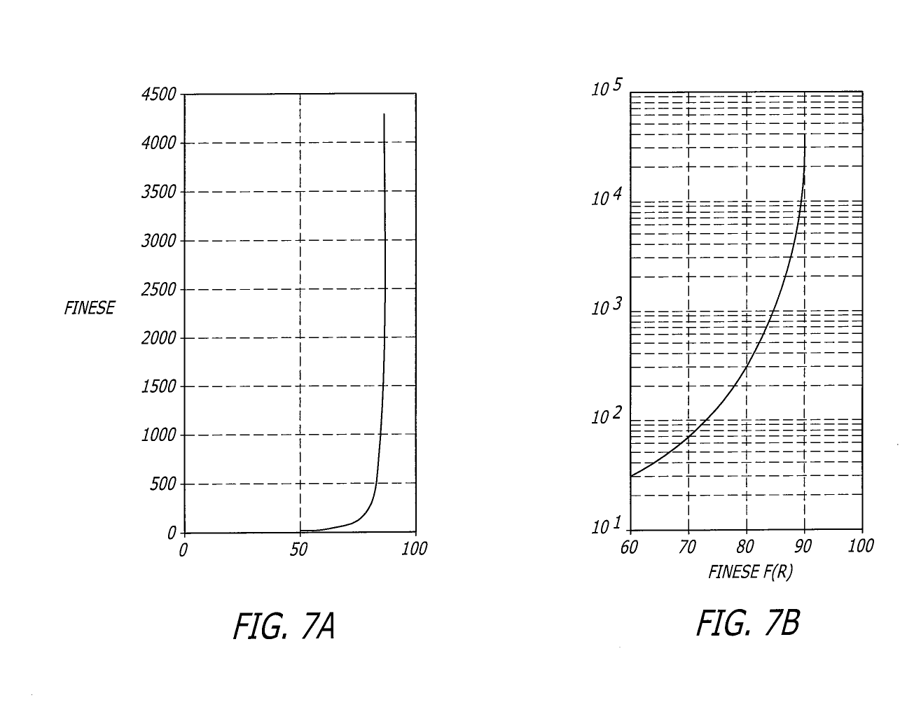

As illustrated by the above equations, designing the cavity to have a desired transfer function and fineness requires consideration of the various physical and optical characteristics of the cavity, such as, for example, flatness of the mirrors, the distance between the mirrors, angle of parallelism between the mirrors, any coating applied to the mirrors, any chemical or thermal expansion and the like of the materials used to fabricate the cavity, as well as the beam diameter of the light incident on the cavity. FIGS. 7A and 7B show the fineness of a cavity as a function of the optical and physical properties of the mirrors.

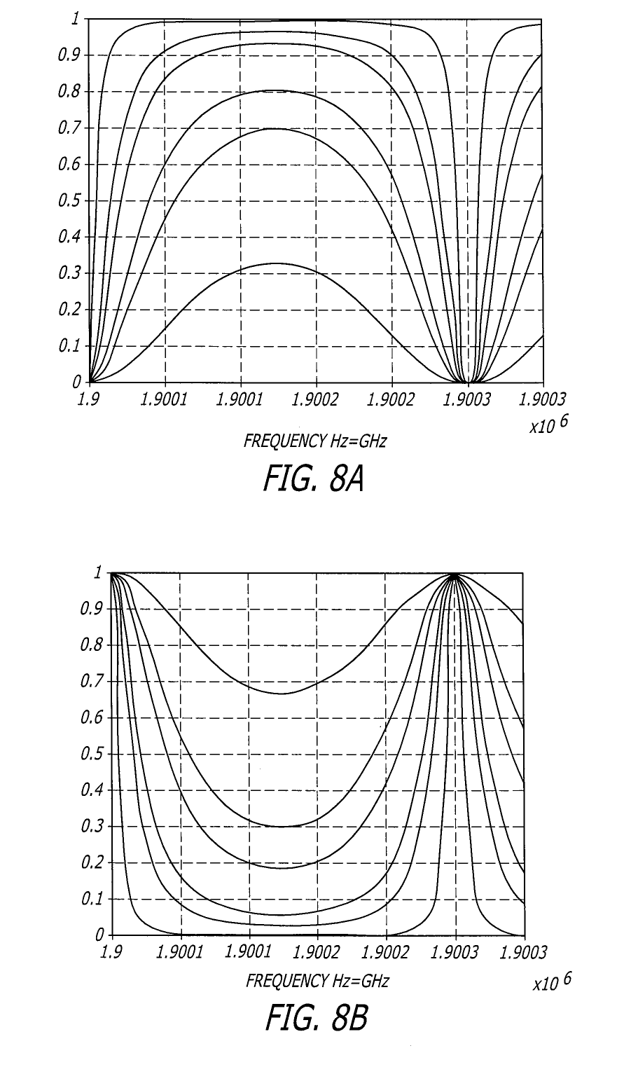

FIGS. 8A and 8B illustrate the reflectance of a cavity as a function of frequency based on fineness of the cavity. As the fineness increases, the cavity becomes more selective, acting similarly to a resonant high Q bandpass filter. In the illustrated case, the higher the Q or fineness, the better the response of the cavity which is determined by comparing the peak to the valleys of the graphed functions. Note, since the cavity is pressurized and temperature controlled, index of refraction, fineness and other properties are typically well behaved to give a constant free spectral range and a well understood response as illustrated by the equations below:

$$〈 {i}_{FN}^{2} 〉 = {S}_{f} ( f ) {( {R}_{0} \overline{P} )}^{2} {\vert \frac{d {T}_{Etalon} ( f )}{d f} \vert}_{T = \frac{Tma x - Tm i n}{2}}^{2} = {RDFN ( {R}_{0} \overline{P} )}^{2}$$

$$RDFN = {S}_{f} ( f ) {\vert \frac{d {{T}_{Etalon} ( f )}^{2}}{d f} \vert}_{T = \frac{Tma x - Tm i n}{2}}^{2}$$

RDFN, that is, Relative Detected Frequency Noise, is the intensity modulation caused by the detection of the laser frequency noise. It is in the same units, and can be directly compared to RIN, or Relative Intensity Noise, of the laser. The amount by which the RDFN exceeds the residual laser RIN and system noise, such as that inherent in the photo-receivers, is the limit of Frequency or Phase Noise cancellation possible using the principles of the present invention. As shown above, RDFN is quantified by determining the discrimination slope of the cavity (etalon) transmission at the operating point of the laser. The caparison point selected is typically the photo-detector current. This allows establishment of the relative noise levels at a common point in the system.

As stated previously, several designs for the cavity exist and may be used, depending only on the needs of the designer. For example, a flat-flat type cavity may be used, where both mirrors of the cavity are flat. Alternatively, one mirror of the cavity may be flat and the other mirror of the cavity may be curved, or both mirrors of the cavity be curved. All of these conditions affect the properties of the laser cavity that is, the fineness, the transfer function and the like. In addition to the above described cavities, there are two additional cavity types: solid, in which the two mirrors are attached to a solid material, or air gap cavities, where there is an empty space between the two mirrors. Both of these types of cavities have different operating properties.

The index of refraction as well as the reflectivity of cavities changes as a function of temperature. Accordingly, air gap cavities are typically used because they have a lower coefficient of thermal expansion and therefore have less sensitivity with respect to temperature, especially if it is desired to conservation of the peak frequency at which the cavity resonates is desirable, than solid type cavities. Both temperature control and pressurization (in the case of a pressurized cavity) are used to keep the optical cavity at a constant pressure inside the air gap. The temperature of the cavity may also be varied to compensate and fine-tune the operating frequency of the cavity. Moreover, once the cavity is set in place with respect to the incoming light beam, final tuning of the cavity may be accomplished by varying the angle of the cavity to the light beam.

It is desired to minimize the weighted mean square error to decide if the performance of the laser takes into account all possible noise sources, and the system and method of the present invention may be programmed to adjust the equations used to provide these solutions. The cost factor selected to be used in the solution of the equations determining the error signal also helps to emphasize the parameter of the system which is desired to be optimized.

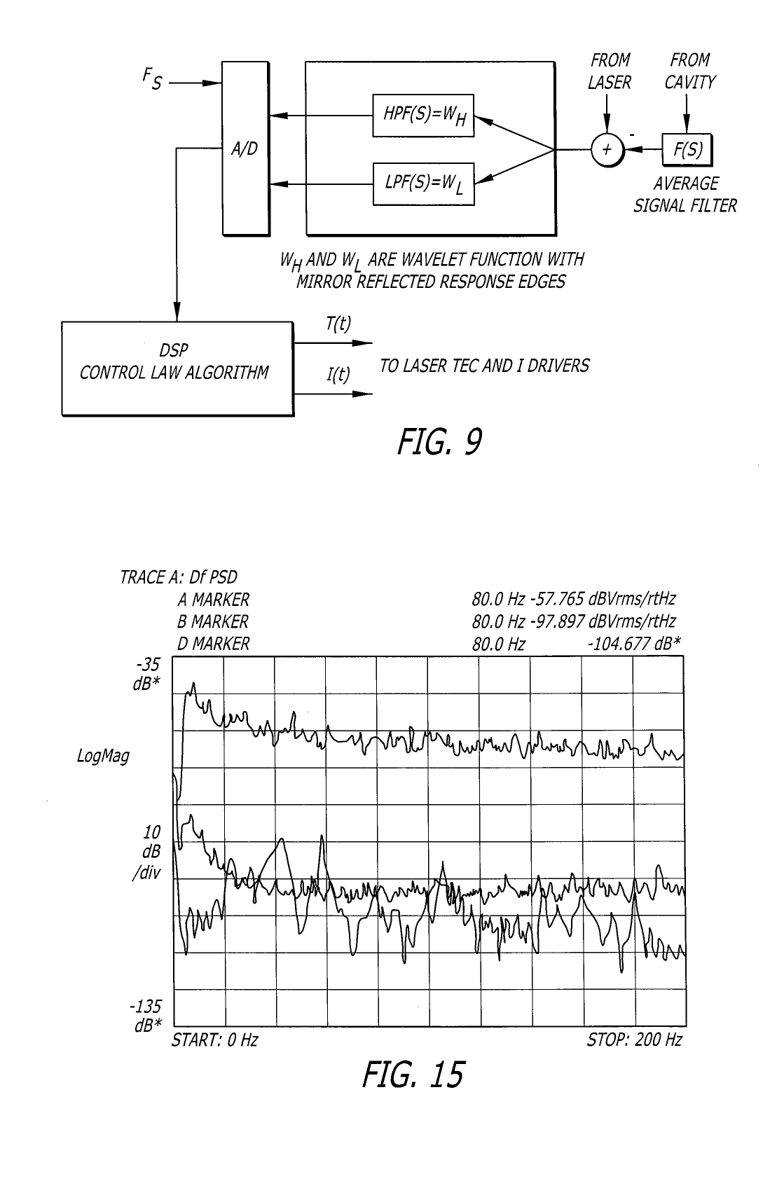

Referring again to FIG. 2, the error feedback loop filter is the first element after the trans-impedance amplifiers 135, 150. A more detailed illustration of the error feedback loop filter is shown in FIG. 9. When the reference cavity 115 response is averaged, the optical cavity frequency response changes as the frequency approaches the resonator frequency of the optical cavity. When the cavity response is averaged, frequencies lower than that of the resonator optical cavity (within the FSR of interest) have a different phase sign than frequencies higher than the resonator optical cavity. Because of this, a wavelet filter, like a Walsh function for a low pass filter can be used to create error signals that allow the minimization of the frequency from locations to the right and left side, thus allowing a minimization of the line width of the semiconductor laser. Where a high pass filter is required, the components of high and low frequencies have different phases, and so would also point to the same positions.

Referring now to FIG. 9, both error signals pass through analog to digital converters and re then communicated to a digital signal processing (DSP) chip. The DSP chip controls the analog to digital conversions, the active controller and the estimation algorithms. The outputs of the DSP chip are temperature T(t) and driver current I(t) for the laser which are used control the laser to obtain the desired performance.

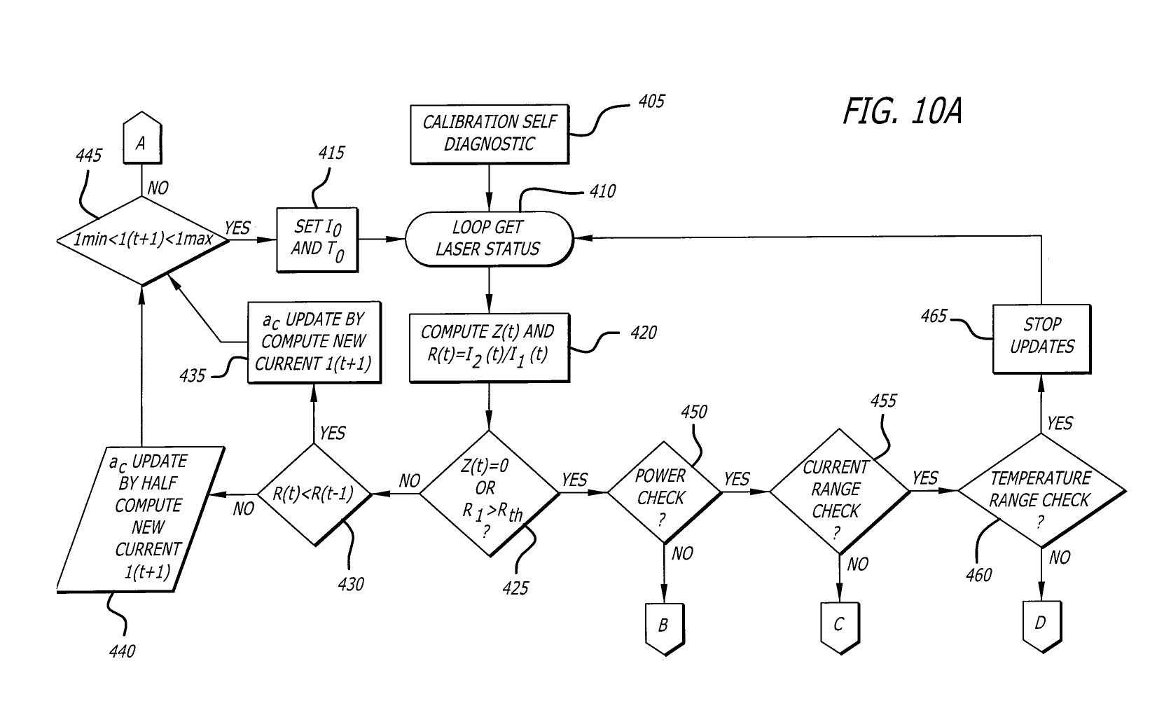

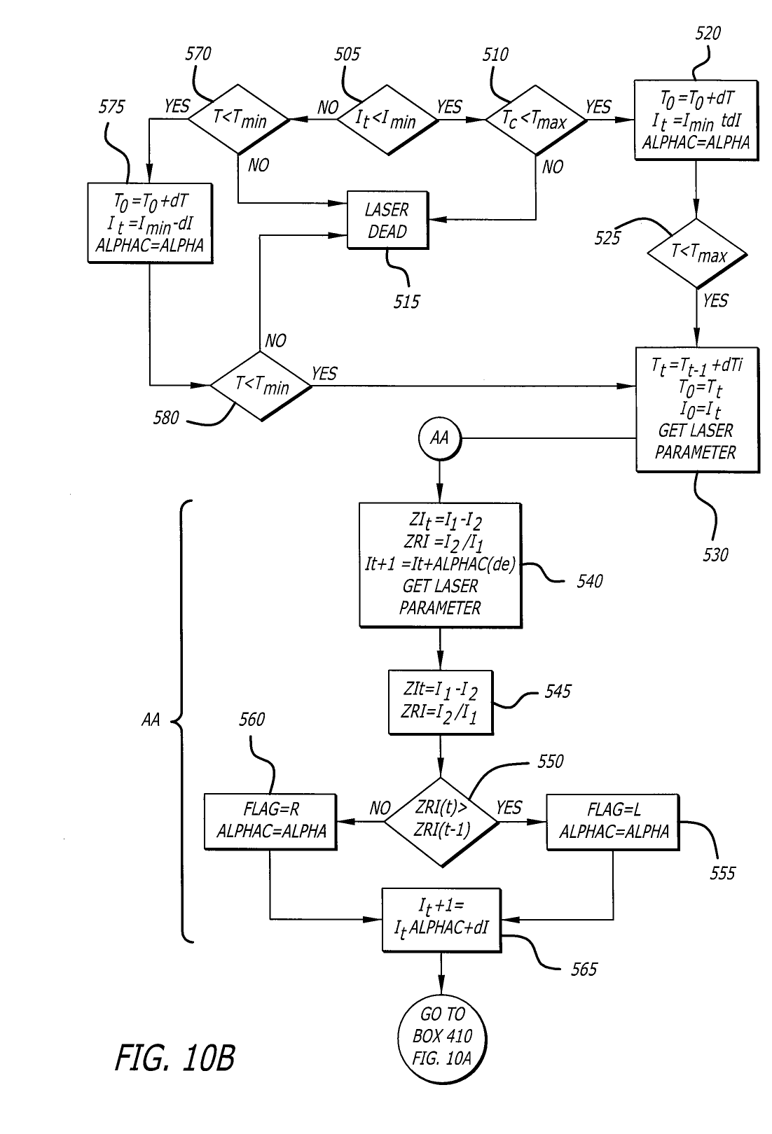

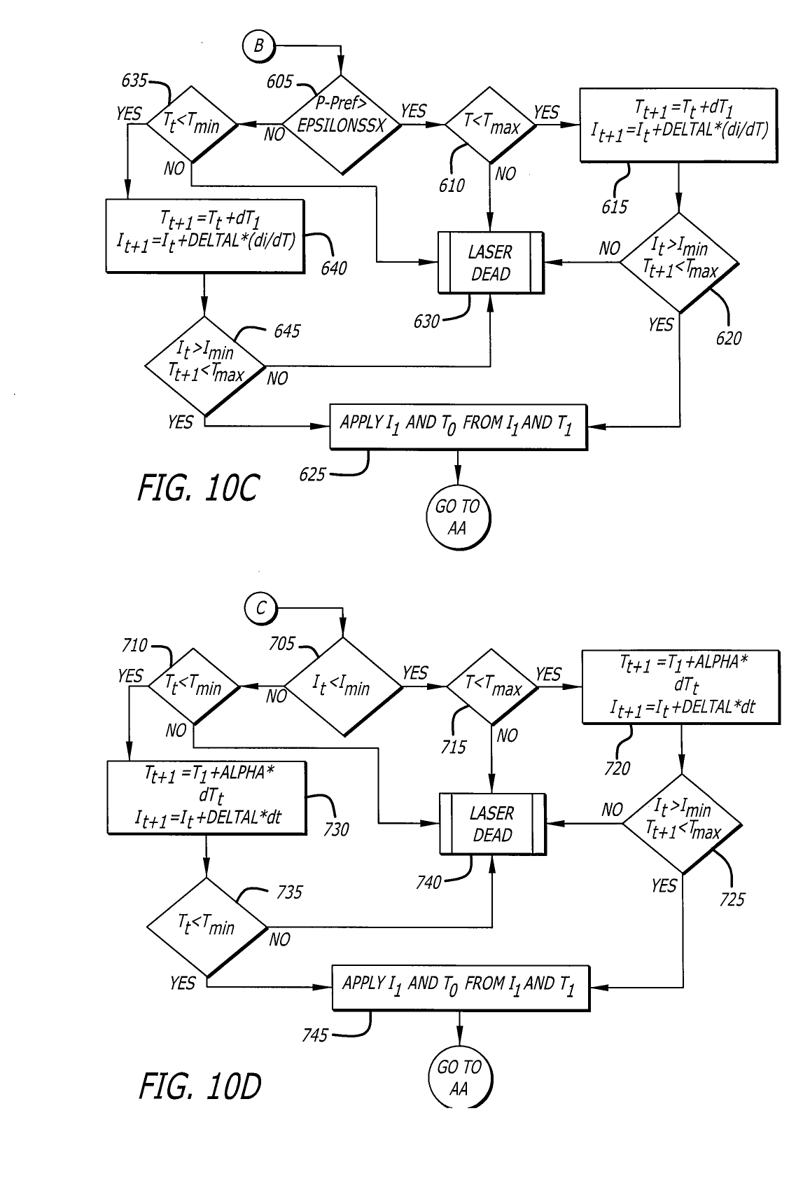

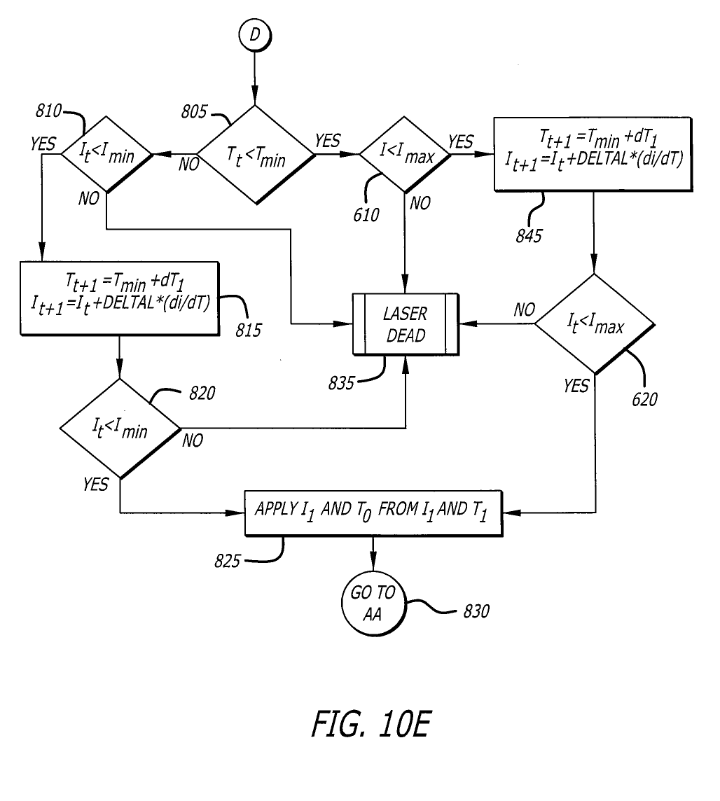

One embodiment of an adaptive algorithm in accordance with principles of the present invention and which is programmed in such a way as to be executed by the controller of the present invention is illustrated in FIGS. 10A, 10B, 10C, 10D and 10E. In this example, the frequency and phase response of the laser is optimized. The embodiments of the patent allows for other algorithms to be used in order to optimize the performance of the laser with respect to RIN, line width, power stability, etc. The structure of the particular algorithm used will be similar to those represented in FIGS. 10A to 10E, but will, of course, be related to the specific parameters being optimized.

When the steps of the control algorithm are initiated, calibration and self-diagnostic routines are first carried out so that several internal variables that control the behavior of the semiconductor laser are obtained. For example, an operating point is derived by using adaptive minimization algorithms. Once the operating point is derived, a simplified state space model is obtained to describe the behavior of the semiconductor laser around or about the chosen operation point (as shown in FIG. 10A). Thereafter, the optimal control laws are derived for the simplified state space model of the laser where an estimate of the internal state variables are computed and smoothed in order to be used in the construction of the feedback signal that optimizes the performance of the laser.

A detailed description of the control algorithm illustrated in FIGS. 10A through 10E is now described. Beginning with FIG. 10A, once the diagnostics and calibration of the system are completed in box 405, the semiconductor laser status at the moment is determined in box 410. In other words, a programmed routine is carried out by the controller to monitor various inputs, such as I₀ and T₀, set in box 415, and sensors, and use the values provided by those inputs and sensors to determine the values of laser output power, frequency and internal state variables. Thereafter, the error signal Z(t) (the optical cavity frequency minus the laser output) and the signal ratio R(t) of the laser is computed in box 420. The signal ratio of the laser is the intensity of the output of the cavity divided by the intensity output of the laser. Consequently, a convergence determination step is carried out in box 425 where it is determined whether the error Z(t) is equal to zero (or close to it). If the error is close to zero, convergence has been achieved. If the error is not close to zero, then the program branches to boxes 430, 435, 440, 445 and 415 as needed to increase or decrease input current and temperature of the laser to the value of the ratio R(t) in order to drive the error Z(t) to zero.

Once convergence is obtained as determined in box 425, a test is performed to see if the power is at a desired level in box 450. If the power level is correct, then a current range is checked in box 455 to make sure that the laser is not being over- or under-driven and that it is within the manufacturer's stated operating range. If the current range is correct, then a temperature range check is performed in box 460. If the temperature range check is correct, then updating is discontinued in box 465 since convergence has been obtained. In such case, the laser status is determined again and then the process is sent back to the loop in box 410.

If convergence is not declared in box 425, the program branches to box 430 where the previous ratio R(t−1) is compared to the current ratio R(t). If R(t) is greater than R(t−1), then new currents are computed and the step cycle is updated in box 435. Searching for the cost function is a unique minimum algorithm function which is similar to the least means squared algorithm typically used in the industry in order to set the operating point, that is, the temperature and driver current of the laser. If the current is in the recommended range as determined in box 445, a new current and temperature are set in box 415 and input into the laser status loop of box 410. If the current is not within the recommended range, then the program branches to subroutine “A” illustrated in FIG. 10B to determine why the new calculated current cannot be used. This subroutine, as will be described in more detail below, may also determine that the current may be substantially reduced and new temperature and current values may be calculated to determine if another mode of the laser is available to lock into.

In Subroutine “A” illustrated in FIG. 10B, a subroutine embodied in box 505 tests to determine whether the current of the semiconductor laser exceeds the limits recommended by the semiconductor laser manufacturer. It the current is less than the manufacture's limit, a determination of whether the temperature T of the laser is less than the maximum temperature which the semiconductor junction of the laser can tolerate in box 510. If the actual temperature is over the maximum, the laser is declared dead in box 515 and the process is ended. If the temperature is lower than the maximum allowable temperature, additional heat is applied to the junction and the current is recalculated in box 520.

The drive current is also tested in box 520 to determine if it is smaller than the minimum current needed to obtain laser emission. If the drive current is smaller than the minimum, additional heat is applied to the semiconductor junction. Again, test the current to ensure it did not go over the maximum current level value. The temperature is again tested in box 525 to ensure that it has not exceeded the maximum allowable temperature. If temperature is less than the maximum, then the new temperature and current are set and the laser parameters are determined in box 530.

Once the laser parameters are determined, the output and ratio of the cavity (denoted by Z(t) and R(t), respectively, where R(t) is the ratio of the intensity and Z(t) which is the output of the cavity at time t) are calculated in box 540. The output and ratio of the cavity are used to update the current in box 545. The ratios are again tested in box 550. If the present ratio is greater than the previous ration, the current is decreased in box 555 because the system is moving away from the optimal solution. If the ratio decreases, that is, the present ratio is less than the previous ration, then a flag is set in box 560 to determine which side of the cost function the system is on. If the system is determined to be moving to the right of the cost function, then the programming continues to move to the right by increasing the current box 565. If the system is moving to the left of the cost function, then the current is decreased in box 565 to move the operating point to the top of the peak of the function, which minimizes the cost function. Thereafter, the program branches back to box 410 of FIG. 10A and the process of FIG. 10A is repeated.

For further reference, it will be seen that boxes 540 through 564 of FIG. 10B form a subloop AA. This subloop AA will be referred to by elements of the programmed subroutines that will be described in more detail below.

If the comparison carried out in box 505 is not true, that is, if the current intensity is greater than the minimum intensity, the temperature of the laser is checked in box 570 to determine if the temperature is greater than a minimum temperature for the laser. If the temperature is greater than the minimum temperature, the program branches to box 575, where temperature and intensity are adjusted and passed to box 580. If the temperature is not greater than the minimum temperature, the program branches to box 530, and the process continues as described above. If the temperature is found to be less than the minimum temperature in boxes 570 or 580, the program branches to box 515 and the laser is declared dead, and the process stops.

FIG. 10C illustrates an embodiment of the programmed method that is followed depending on the outcome of the power check performed in box 450 of FIG. 10A to determine the desired optimum power to drive the laser, at least within the desired output power error. In box 605, the output power of the laser is compared to see if it is within a specified ripple value. If the output power is within the specified ripple, the temperature of the laser is checked in box 610 to determine if it is below the maximum allowable temperature for the laser. If the temperature is below the maximum, the power may be adjusted upward, as determined in box 615. If the output power is determined to be above the maximum ripple but the temperature is below the maximum in box 620, then the temperature of the laser may be reduced even more to increase output power in box 625. Nevertheless, if the temperature is above the maximum temperature and the ripple is above the maximum ripple, the laser is declared dead in box 630 and the process is ended.

If the ripple is above the maximum allowed, it should be reduced and the temperature and current should be calculated again in order to increase the output power. The temperature and current are calculated again to make sure they are below the maximum and above the minimum in boxes 635, 640 and 645. In these steps, the maximum temperature is verified to be above the minimum temperature, the temperature is updated, and the current is verified to be below the maximum and above the minimum (within parameters). If any of these tests fail, the program branches to box 630 and the laser is determined to be dead and the process is ended. If all tests pass, the laser parameters are calculated again in box 625.

As stated previously, boxes 540 through 564 of FIG. 10B form a subloop AA. Once the laser parameters are calculated in box 625 of FIG. 10C, the program branches to subloop AA, where the program is executed as described previously. When all of the criteria of subloop AA are satisfied, the current and temperature are updated and passed back to box 410 of FIG. 10A.

Referring now to FIG. 10D, Subroutine C will now be described. Subroutine C is executed when the power check of box 450 of FIG. 10A passed but the current range check of box 455 did not. If the proposed operating current is not within the current range provided by the semiconductor laser manufacturer, subroutine C is executed.

In this subroutine, the actual current is determined to be smaller or larger than the minimum current to operate the laser in box 705. If the actual current is larger than the minimum current, then the temperature of the laser is checked in box 710. If the actual current is smaller than the minimum current, the temperature is checked in box 715. In this case, the current must be increased in box 720. In doing so, the temperature also needs to be decreased in order to maintain the same operating conditions. Once adjusted, the temperature is tested to determine if it is lower than the maximum temperature in box 725. If the temperature is less than the maximum temperature allowed, then the program branches to box 745.

If the current is determined in box 705 to be larger than the minimum current, the temperature is checked in box 710 to determine if the temperature is greater than the minimum allowable operating temperature. If the temperature is greater than the minimum temperature, the temperature may be reduced and the current increased as needed in box 730. The temperature is again checked in box 735 to see if the temperature is still greater than the minimum. If it is greater than the minimum, the program branches to box 745.

The temperature and current are updated in box 745, and then passed on to subroutine AA of FIG. 10B for further processing to recalculate the ratios and checked to see if a move to the right on the cost function needs to occur. When subroutine AA is complete, the program branches back to box 410 of FIG. 10A.

If the comparisons and tests carried out in boxes 710, 715, 725 and 735 result in a false or untrue condition, then the program branches to box 740. The laser is declared dead in box 740 and the process terminates.

Referring now to FIG. 10E, subroutine D will now be described. Subroutine D is executed when the temperature range check performed in box 460 of FIG. 10A fails. When that comparison fails, the program branches to subroutine D, where a determination is made in box 805 if the new proposed temperature is lower than the minimum temperature for the laser as allowed by the manufacturer. If the temperature is not less than the minimum temperature in box 805, a determination is made in box 810 whether the current is greater than the minimum current needed to excite the laser. If the current is greater that the minimum current, the temperature is decreased and the current is recalculated in box 815

The current is again checked in box 820 to determine if it is greater than the minimum current. If so, then the program branches to box 825, where new current and temperature values are applied, and the process then branches to subroutine AA of FIG. 10B in box 830. When subroutine AA is completed, the program branches back to box 410 of FIG. 10A.

If the new current is not greater than the minimum current in boxes 810 and 820, the laser is determined to be dead in box 835 and the process is ended. If the temperature is less than the minimum temperature in box 805 and the current is less than the maximum current in box 840, the temperature of the laser junction is increased the current is recalculated in box 845. If the new current is now greater than the maximum current, as determined in box 850, the program branches to box 835 and the laser is determined to be dead and the process is ended. If the new current is less than the maximum current, the program branches to box 825 where the new current and temperature is applied, and the process then branches to subroutine AA of FIG. 10B in box 830. When subroutine AA is completed, the program again branches back to box 410 of FIG. 10A.

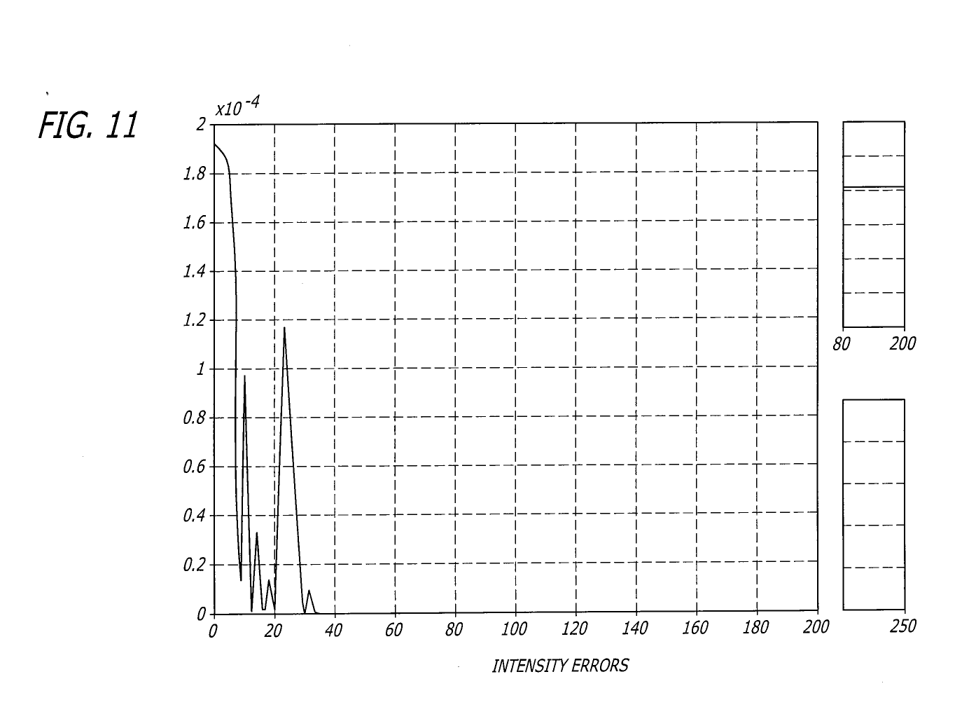

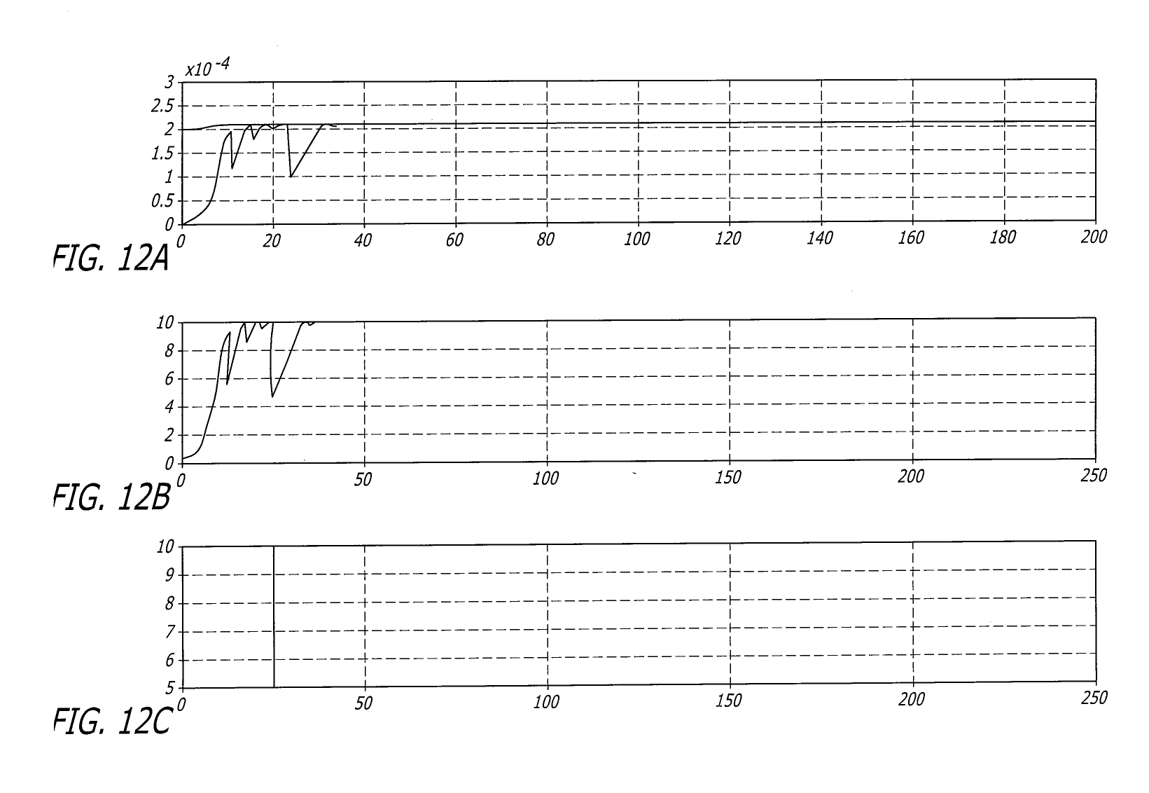

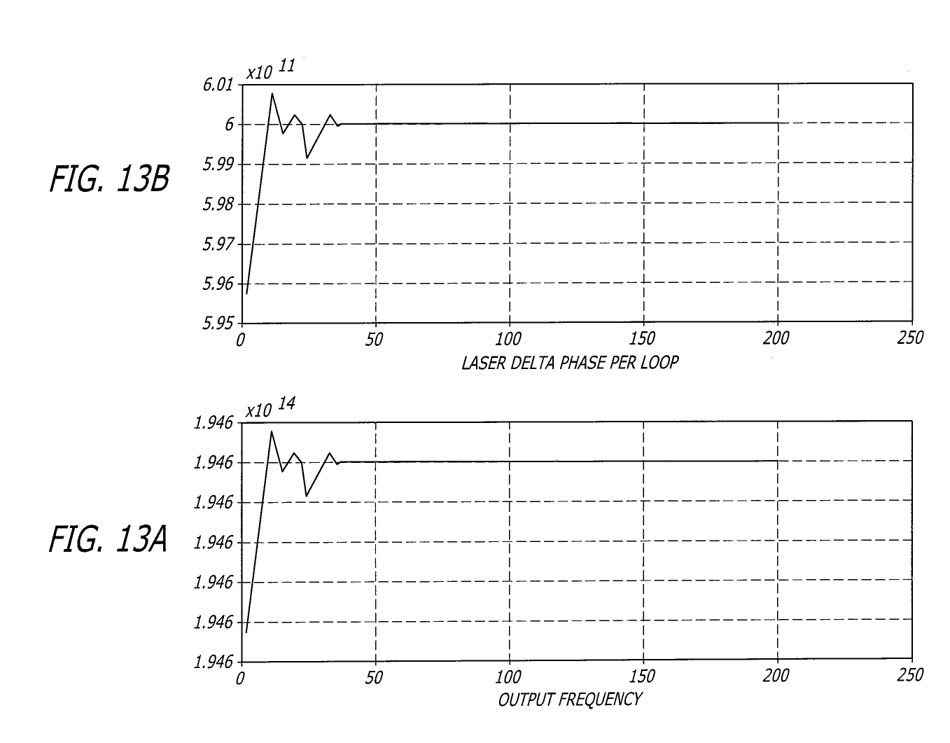

The results of the adaptive algorithm to obtain an operating point are depicted in FIGS. 11, 12A-C and 13A-B. FIG. 11 shows the results of intensity errors as a function of duration time for the laser. FIGS. 12A, 12B and 12C show Intensity Values and Ratios as a function of time, and FIGS. 13A and 13B show laser delta phase per loop and output frequency as a function of duration time for the laser.

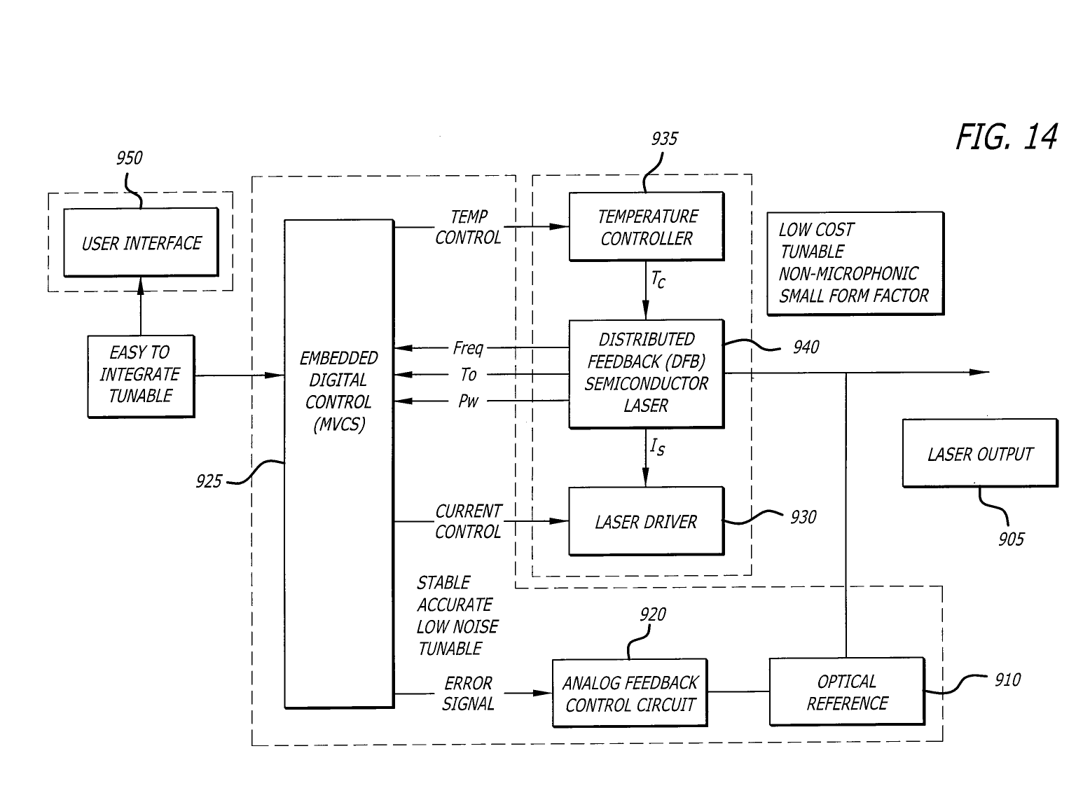

FIG. 14 is a system functional block diagram of one embodiment the present invention. The process depicted in this figure is functionally equivalent to the system depicted in FIG. 2. Referring to FIG. 14, the laser output 905 is coupled to an optical reference 910. The optical reference 910 is coupled to an analog feedback control circuit 920 and the analog feedback control circuit is coupled to an embedded digital control (MVCS) 925. The embedded digital control (MVCS) is also coupled to a laser driver 930, temperature controller 935, distributed feedback (DFB) Semiconductor Laser 940 and user interface 950.

Utilizing the principles of the system and methods of the present invention, it is possible to obtain improved laser performance. For example, a semiconductor laser light source may be manufactured having long term stability within about 2.0 picometers and short term stability within about 0.04 picometers, significant improvements over prior devices. Moreover, a single laser may be tuned within a range of about 3 nanometers, and a laser array may be tuned within a range of about 51.2 nanometers. Furthermore, the minimum step size may be in the range of about 0.5 picometers.

The system and methods of the present invention also provide for reduced noise level and improved spectral width. For example, RIN is in the range of about −160 dB/Hertz, side mode suppression may be in the range of −35 db, and spectral width may be in the range of 500 kHz. Power output of a semiconductor laser in such a system may be in the range of about 13 dBm. A principle advantage to the present invention is that all of the above improved performance levels are available in a relatively small sized light source. For example, one embodiment of the present invention was constructed having dimensions of three inches by four inches by one half inch thick.

FIG. 15 illustrates the improvements possible using the one example of a semiconductor laser source in constructed and functioning in accordance with system and method of the present invention. FIG. 15 shows a typical response from a regular DFB laser without the present invention, a regular DFB laser with the present invention and a fiber laser. It is easily observed that the present invention provides a laser source that has performance comparable to a much more expensive and less robust laser system, which significantly improving over the performance of previous semiconductor lasers.

While several particular forms of the invention have been illustrated and described, it will be apparent that various modifications can be made without departing from the spirit and scope of the invention.

What is claimed is:

1. A wavelength source control system, comprising:
an optical control feedback element; and
a wavelength source element coupled to the optical control feedback element;
wherein the optical control feedback element is adapted to:
sample a wavelength source element output;
determine an error signal based on the sampled wavelength source element output; and
transmit a set of control signals comprising a current control signal and temperature control signal to the wavelength source element wherein the set of control signals are based on the error signal and a frequency of the output, a temperature of the wavelength source element and an output power of the wavelength source element.

2. The apparatus according to claim 1, wherein the optical control feedback element comprises an optical source reference, an analog feedback and a digital control element adapted to generate the current control signal and temperature control signal.

3. The apparatus according to claim 1, wherein the wavelength source element comprises a laser, laser driver and temperature control element.

4. A wavelength source control method, comprising:
sampling a wavelength source element output;
determining an error signal based on the sampled wavelength source element output; and
transmitting a set of control signals comprising a current control signal and temperature control signal wherein the set of control signals are based on the error signal and a frequency of a wavelength source element, a temperature of the wavelength source element and an output power of the wavelength source element.

5. A method for controlling the wavelength output of a laser, comprising:
sampling an output of a laser;
determining a control law related to at least one selected parameter that is an input of the laser;
applying the control law to the output of the laser; and
operating the laser in accordance with the control law.

6. The method of claim 5, wherein determining the control law includes determining a cost function related to the output of the laser.

7. The method of claim 6, further comprising optimizing the cost function to obtain a desired operational condition of the laser.

8. The method of claim 5, wherein sampling the output of the laser includes sampling an intensity parameter and a temperature parameter.

9. The method of claim 8, wherein the control law is applied to alter the intensity of the laser.

10. The method of claim 8, wherein the control law is applied to alter the temperature of an active region of the laser.

11. The method of claim 8, wherein determining a control law includes comparing the output of the laser to a response of an optical cavity.

12. The method of claim 8, wherein determining a control law includes determining an error signal.

13. The method of claim 12, wherein determining an error signal includes smoothing the error signal to remove background noise from the signal.

14. The method of claim 8, wherein determining a control law includes non-linear minimization and parameter estimation and determining a space state model of the laser.

15. The method of claim 8, wherein sampling the output of the laser includes splitting the output of the laser using a beam splitter into a first beam and a second beam,
splitting the second beam into a third beam and a fourth beam using a polarizing beam splitter,
communicating the third beam to an optical cavity,
sampling an output of the optical cavity,
communicating the sampled output of the optical cavity to a first photodector,
communicating the fourth beam to a second photodetector,
determining an error signal from an output from the first photodetector and the second photodetector.

16. The method of claim 8, wherein the laser is a semiconductor laser.
